(19) United States
(12) Patent Application Publication
(10) Pub. No.: US 2001/0042916 A1
(43) Pub. Date: Nov. 22, 2001

(54) Semiconductor device and method of manufacturing the same

(76) Inventor: Naoto Kimura, Kumamoto (JP)

Correspondence Address: ROSENMAN & COLIN LLP, 575 MADISON AVENUE, NEW YORK, NY, 10022-2585, US

(21) Appl. No.: 09/886,844

(22) Filed: Jun. 21, 2001

(30) Foreign Application Priority Data
Apr. 7, 2000 (JP) 2000-202248

(51) Int. Cl. H01L 23/52; H01L 23/48

(52) U.S. Cl. 257/738; 257/774; 257/737; 257/778

(57) ABSTRACT

A semiconductor device is provided with a semiconductor chip. A plurality of electrode pads are arranged in rows running in a first direction on a surface of the semiconductor chip. The semiconductor device is provided with a substrate bonded to the surface, solder balls formed on the substrate, and wires for connecting the solder balls respectively to the corresponding electrode pads. A first slit matching the electrode pads and running in the first direction and a second slit running in a second direction perpendicular to the first direction are provided to the substrate to divide the substrate into at least four regions.

### BACKGROUND OF THE INVENTION

1. Field of the Invention

The present invention relates to a semiconductor device provided with a package showing a CSP (chip size package) and a BGA (ball grid array) structure or the like and a method of manufacturing such a semiconductor device, in particular, to a semiconductor device designed with emphasis on reliability and a method of manufacturing such a semiconductor device.

2. Description of the Related Art

Semiconductor devices provided with a package showing a CSP (chip size package) and a BGA (ball grid array) structure has been developed in line with the trend toward a higher degree of integration of functional semiconductor elements having a large number of pins and also the trend toward realization of larger-scale semiconductor chips. Japanese Patent Laid-Open Publication No. 2000-68405 describes such a semiconductor device. FIG. 1 schematically illustrates a semiconductor device similar to the one disclosed in Japanese Patent Laid-Open Publication No. 2000-68405 particularly in terms of structure.

A semiconductor device according to the above identified publication includes an oblong semiconductor chip (not shown) mounted on a base substrate 21 made of glass epoxy resin by means of an adhesive agent. The base substrate 21 has a profile substantially same as that of the semiconductor chip. The base substrate 21 is provided with a longitudinally extending center slit 22. The semiconductor chip is provided with electrode pads (not shown) arranged in a region matching the center slit 22 to be exposed from the center slit 22. Furthermore, power supply wire conductors and grounding wire conductors extending externally from the center slit 22 are provided to the base substrate 21. The electrode pads are connected to the corresponding conductor wires by way of respective bonding wires (metal wires). Solder balls 20 are arranged on the base substrate 21 and connected to the corresponding wire conductors by way of respective internal wires.

Such a semiconductor device shows improved electric characteristics because of the remarkably reduced electric resistance of the wire conductors.

However, the print circuit board carrying such a semiconductor device is accompanied by a problem that some of the solder balls 20 bonded to the corresponding electrically conductive pads of the print circuit board can be broken when the ambient temperature rises.

This phenomenon is believed to occur for the reasons described below. The thermal expansion coefficient of the base substrate 21 made of glass epoxy resin is greater than that of the semiconductor chip. Therefore, as the ambient temperature rises, the thermal expansion of the base substrate 21 is restricted by the semiconductor chip and hence the base substrate 21 does not expand sufficiently. As a result, the base substrate 21 expands remarkably in the longitudinal direction along the center slit 22 as indicated by arrows in FIG. 1 rather than in the direction perpendicular to the center slit 22. Additionally, the thermal expansion coefficient of the print circuit board carrying the semiconductor device is substantially same as that of the base substrate. Therefore, the solder balls 20 of the base substrate and the corresponding conductive pads of the print circuit board bonded to the respective solder balls become displaced relative to each other when the device is subjected to thermal expansion.

However, since the solder balls and the corresponding conductive pads are bonded to each other, the connecting surface of each of the solder ball and the corresponding one of the conductive pad and/or the solder ball itself are subjected to shearing stress that may vary as a function of the displacement. As a result, some of the solder balls can become broken. Particularly, the stress of the solder balls located most remotely from the center of the substrate will be maximal. Therefore those solder balls will highly probably become broken when the device is thermally expanded beyond a certain limit.

### SUMMARY OF THE INVENTION

It is an object of the present invention to provide a semiconductor device that is highly reliable and whose solder balls would not become broken regardless of any temperature rise after the device is assembled to the print circuit board, and a method of manufacturing such a semiconductor device.

According to one aspect of the present invention, a semiconductor device comprises a semiconductor chip which has a plurality of electrode pads arranged in a first direction on a first surface thereof, a substrate bonded to the first surface, solder balls formed on the substrate, and wires respectively connecting the solder balls and corresponding electrode pads. A first slit matching the electrode pads and extending in the first direction and a second slit extending in a direction perpendicular to the first direction are provided to the substrate. The substrate is divided into at least four regions.

According to another aspect of the present invention, a method of manufacturing a semiconductor device comprising the step of forming first and second slits in each of a plurality of mounting regions of a substrate member. A semiconductor chip is to be mounted on each of the mounting regions. The first and second slits intersect perpendicularly each other. The method further comprises the step of bonding the semiconductor chips to the substrate member for each of the mounting regions, and dividing the substrate member for each of mounting regions. The semiconductor chip has electrode pads formed in a region matching the first slit.

Thus, according to the invention, slits are formed on the substrate like a cross to divide the substrate so that, when the substrate is thermally expanded, it is not substantially constrained by the semiconductor chip. As a result, the thermal stress applied to the solder balls located between the substrate and the print circuit board is lessened. Therefore, the solder balls are prevented from being broken by thermal stress to improve the reliability of the semiconductor device.

### BRIEF DESCRIPTION OF THE DRAWINGS

FIG. 1 is a schematic illustration of a semiconductor device similar to the one disclosed in Japanese Patent Laid-Open Publication No. 2000-68405 particularly in terms of structure;

FIG. 2A is a plan view of a semiconductor device according to a first embodiment of the present invention;

FIG. 2B is a cross sectional view taken along line A-A in FIG. 2A;

FIG. 3 is a plan view of the semiconductor device shown in FIGS. 2A and 2B as mounted on a print circuit board;

FIG. 4 is a plan view of a semiconductor device according to a second embodiment of the present invention;

FIG. 5 is a flow chart of a method of manufacturing a semiconductor device according to the first embodiment of the present invention; and

FIG. 6 is a plan view of the semiconductor device showing a halfway step of the method of manufacturing the semiconductor device according to the first embodiment.

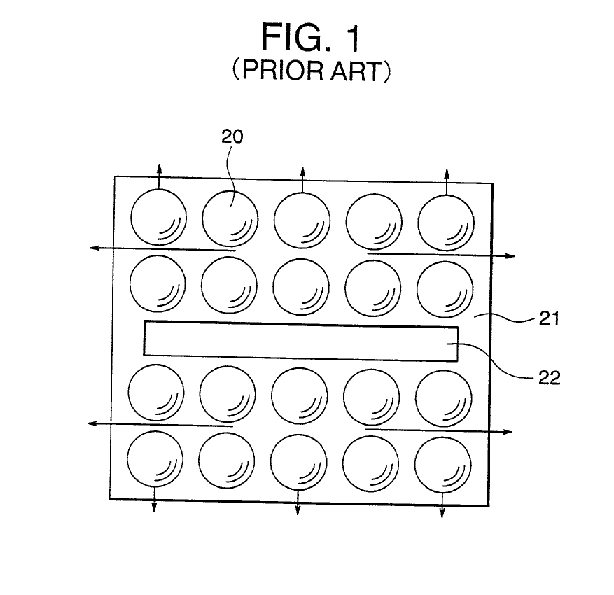

### DETAILED DESCRIPTION OF THE PREFERRED EMBODIMENT

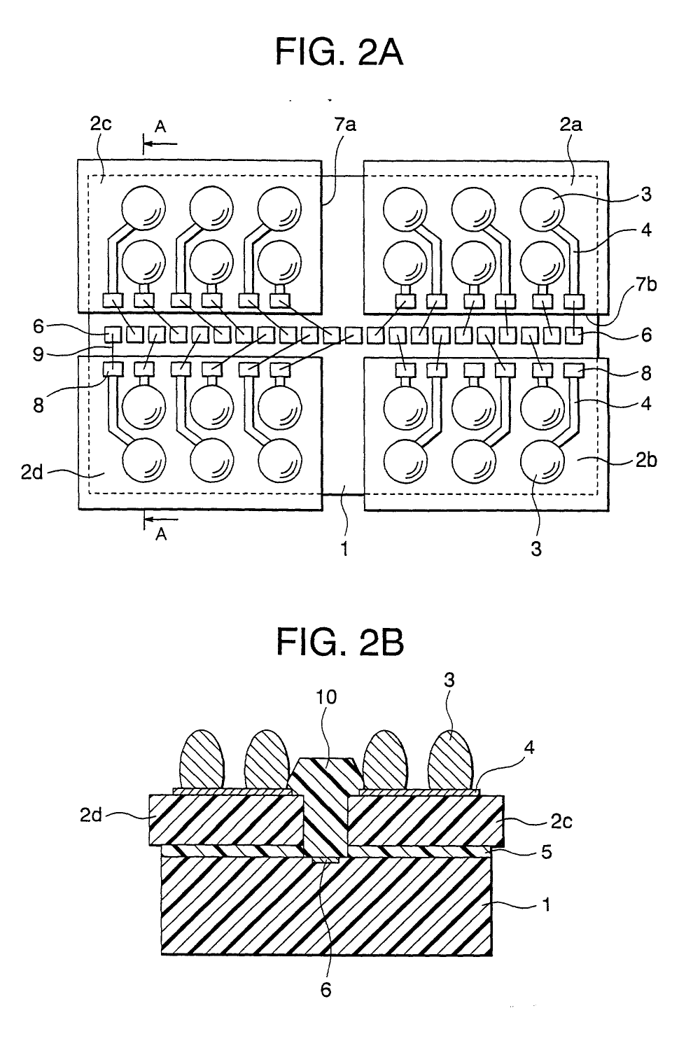

Now, preferred embodiments of the present invention will be described in greater detail by referring to the accompanying drawings. FIG. 2A is a plan view of a semiconductor device according to a first embodiment of the present invention and FIG. 2B is a cross sectional view taken along line A-A in FIG. 2A.

As shown in FIGS. 2A and 2B, the first embodiment is provided with a semiconductor chip 1 containing a number of semiconductor elements (not shown). A plurality of electrode pads 6 are formed on a main surface of the semiconductor chip 1. As shown in FIG. 2A, the electrode pads 6 are arranged, for example, along the longitudinal center line in a transversal direction of the semiconductor chip 1.

Four base substrates 2a, 2b, 2c and 2d are bonded by means of an adhesive agent 5 to the other main surface of the semiconductor chip 1 that does not carry the electrode pads 6. As shown in FIG. 2A, the base substrates 2a, 2b, 2c and 2d are arranged in such a way that they are separated from each other by a longitudinal slit 7b and a transversal slit 7a formed in the semiconductor chip 1. The transversal slit 7a is located at the middle of the longitudinal direction of the semiconductor chip 1, whereas the longitudinal slit 7b is located at the middle of the transversal direction of the semiconductor chip 1. The electrode pads 6 are exposed from the slit 7b.

Electrically conductive pads 8 are formed on the base substrates 2a, 2b, 2c and 2d and respectively connected to the corresponding electrode pads 6 by way of respective bonding-wires 9. Solder balls 3 are respectively connected to the corresponding conductive pads 8 by way of respective wires 4. As shown in FIG. 2B, the slits 7a and 7b are filled with a resin material 10. Note that the resin material 10 is omitted in FIG. 2A.

If the base substrates 2a, 2b, 2c and 2d are made of glass epoxy resin, the adhesive agent 5 is preferably made of synthetic epoxy resin containing acrylic rubber from the viewpoint of cost and adhesion. The bonding-wires 9 may be thin metal wires, which may be gold wires, for example. The wires 4 and the electrically conductive pads 8 are formed on the base substrates 2 by printing, using copper, for example. The slits 7a and 7b are preferably extending from the outer boundary of the semiconductor chip 1 so that the four base substrates 2 are completely separated from each other as will be described hereinafter.

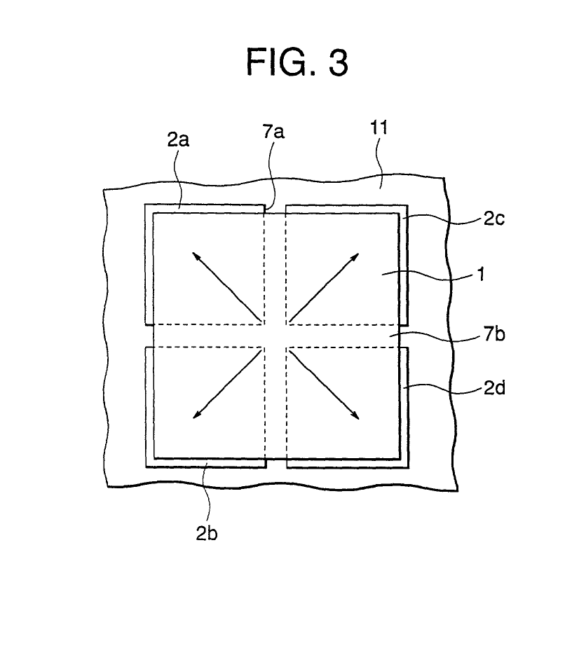

FIG. 3 is a plan view of the semiconductor device shown in FIGS. 2A and 2B as mounted on a print circuit board. When the semiconductor device according to the first embodiment is mounted on a print circuit board 11, the side carrying the base substrates 2a, 2b, 2c and 2d is made to face downward and the solder balls 3 are brought into contact the respective conductive pads of the print circuit board 11. Thereafter, the solder balls 3 are reflowed and bonded to the conductive pads. As a result, the semiconductor device is firmly assembled onto the print circuit board 11.

After the assembling, if the temperature of the semiconductor device rises in operation, the base substrates 2a, 2b, 2c and 2d are not constrained by the other substrate because they are separated from each other. As a result, the print circuit board 11 can easily thermally expand in the direction as indicated by arrows in FIG. 3 and the base substrates 2a, 2b, 2c and 2d will be slightly moved in the direction of the arrows in FIG. 3 by the thermal expansion of the print circuit board 11. Therefore, while the solder balls and the corresponding conductive pads located most remotely from the center are displaced from each other maximally in conventional semiconductor devices, the displacement is minimized in this embodiment. Rather, the solder balls located closest to the center may be displaced most. As a result, the stresses of the solder balls are minimized and the solder balls are prevented from being broken.

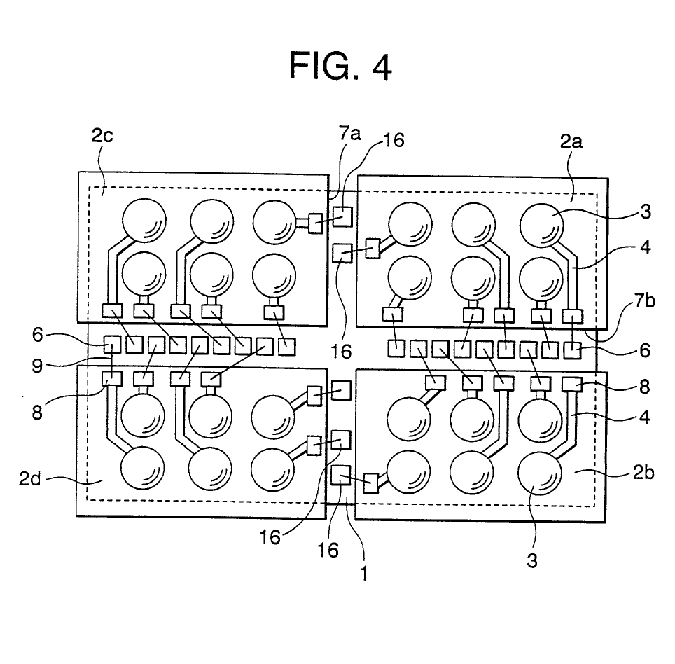

Next, a second embodiment of the invention will be described. FIG. 4 is a plan view of a semiconductor device according to a second embodiment of the present invention. The components of the second embodiment shown in FIG. 4 that are same as their counterparts of the first embodiment shown in FIGS. 2A and 2B are denoted respectively by the same reference symbols and will not be described in detail any further.

As shown in FIG. 4, the second embodiment is provided with electrode pads 16 that are arranged at positions matching the slit 7a of the semiconductor chip 1. The number of the electrode pads 6 located at positions matching the slit 7b may be reduced by the number of the electrode pads 16.

This second embodiment provides an advantage that the distance between each of the conductive pads 8 and the corresponding one of the electrode pads 6 and 16 to reduce the electric resistance between the two pads if compared with the first embodiment. As a result, signals can be transmitted at a higher rate.

While each of the first and second embodiments includes four base substrates 2a, 2b, 2c and 2d, the number of base substrates of a semiconductor device according to the present invention is by no means limited thereto. For example, a semiconductor device may include six or eight base substrates bonded to a single semiconductor chip to further disperse the force with which the semiconductor chip constrains the board. Then, as a result, the thermal stress applied to the solder balls will be further reduced.

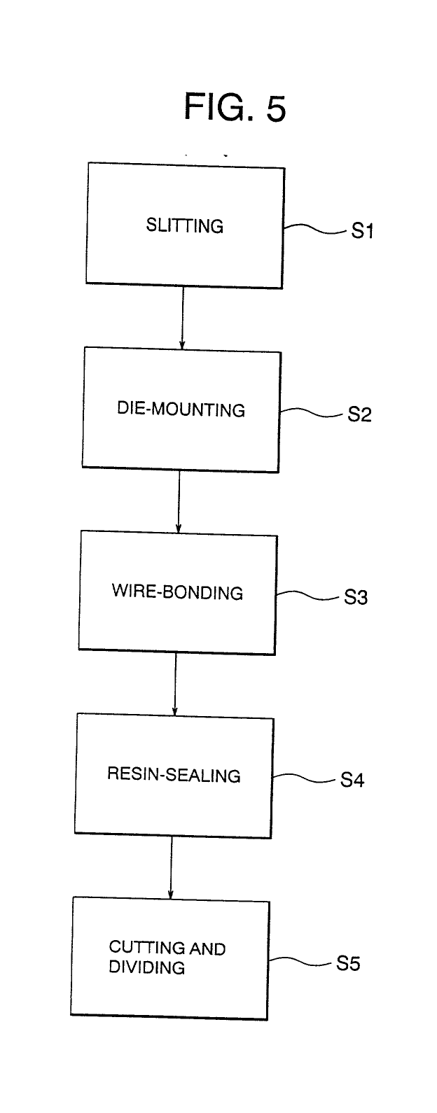

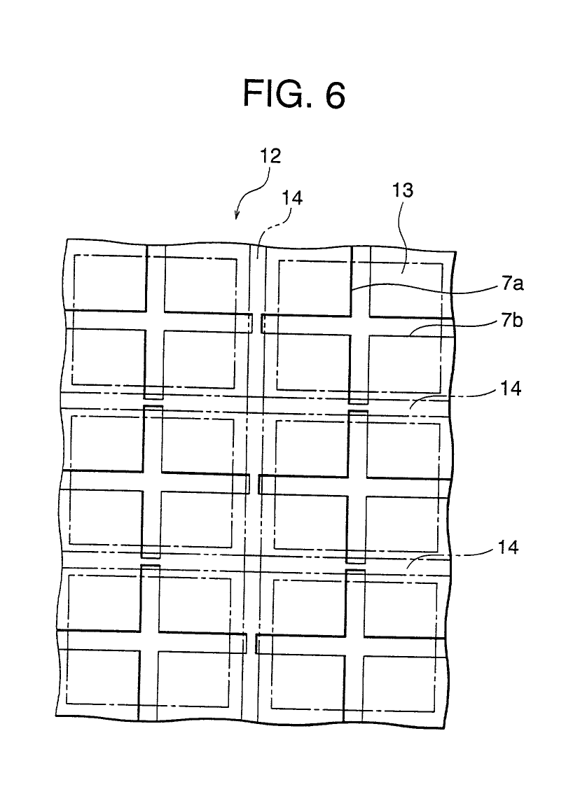

Next, a method of manufacturing a semiconductor device according to the first embodiment will be described. FIG. 5 is a flow chart of a method of manufacturing a semiconductor device according to the first embodiment of the present invention, and FIG. 6 is a plan view of the semiconductor device showing a halfway step of the method of manufacturing the semiconductor device of the first embodiment.

First, crossing slits 7a and 7b are formed in a semiconductor chip mounting regions 13 of a substrate member 12 which carries a print circuit thereon, by press-punching (Step S1). The semiconductor chip mounting regions 13 are arranged in rows and columns. Print circuit may be made on the substrates after forming the slits 7a and 7b.

Then, an adhesive agent is applied to the semiconductor chip mounting regions 13. Subsequently, semiconductor chips are bonded to the respective semiconductor chip mounting regions 13 by means of a die-mounter (not shown) to secure them in position (Step S2).

Thereafter, the substrate member 12 is placed on the stage of wire bonding system (not shown) and the electrode pads 6 and the corresponding electrically conductive pads 8 are connected by respective bonding-wires 9 for each semiconductor chip (Step S3).

Then, the substrate member 12 is set in position in a mold for resin sealing (not shown). Thereafter, molten resin is poured into the space of the slits 7a and 7b. As the resin is cured, the slits 7a and 7b are filled with the resin material 10 (Step S4). Subsequently, solder balls are mounted on respective pads connected to the corresponding wires 4 by means of a solder ball mounting jig (not shown).

Then, a wheel cutter (not shown) is driven to move along cutting lines 14 to divide the substrate member 12 for the semiconductor chip mounting regions 13 (Step S5).

With the above-described manufacturing method, a plurality of semiconductor devices can be manufactured as lot to greatly reduce the manufacturing time. With any conventional methods of manufacturing a semiconductor device, a sequence of manufacturing steps need to be carried out for each semiconductor chip. To the contrary, according to the above-described method, a plurality of semiconductor chips are arranged in rows and columns on a large substrate member and, after assembling the plurality of semiconductor devices, they are separated from each other by cutting the substrate member. Thus, the time required to assemble a single semiconductor device is remarkably reduced.

While a plurality of semiconductor chip mounting regions 13 are arranged in rows and columns on a substrate member 12 in the above description, they may alternatively be arranged in a single row. The number of rows of semiconductor chip mounting regions can be determined appropriately depending on the performance of the die mounter and that of the wire bonding system.

It will be appreciated that the semiconductor device according to the second embodiment can be manufactured by means of the above-described method, with modifying only the arrangement of electrode pads.

What is claimed is:

1. A semiconductor device comprising:
a semiconductor chip which has a plurality of electrode pads arranged in a first direction on a first surface thereof;
a substrate bonded to said first surface, a first slit matching said electrode pads and extending in said first direction and a second slit extending in a direction perpendicular to said first direction being provided to said substrate, and said substrate being divided into at least four regions;
solder balls formed on said substrate; and
wires respectively connecting said solder balls and corresponding electrode pads.

2. The semiconductor device according to claim 1, wherein said slits extends beyond the boundary of said semiconductor chip.

3. The semiconductor device according to claim 1, wherein said semiconductor chip comprises electrode pads at positions matching said second slits.

4. The semiconductor device according to claim 2, wherein said semiconductor chip comprises electrode pads at positions matching said second slits.

5. The semiconductor device according to claim 1, wherein said substrate is made of glass epoxy resin and bonded to said semiconductor chip by means of an adhesive agent made of epoxy resin containing acrylic rubber.

6. The semiconductor device according to claim 2, wherein said substrate is made of glass epoxy resin and bonded to said semiconductor chip by means of an adhesive agent made of epoxy resin containing acrylic rubber.

7. The semiconductor device according to claim 3, wherein said substrate is made of glass epoxy resin and bonded to said semiconductor chip by means of an adhesive agent made of epoxy resin containing acrylic rubber.

8. The semiconductor device according to claim 4, wherein said substrate is made of glass epoxy resin and bonded to said semiconductor chip by means of an adhesive agent made of epoxy resin containing acrylic rubber.

9. A method of manufacturing a semiconductor device comprising the steps of:
forming first and second slits in each of a plurality of mounting regions of a substrate member, a semiconductor chip being to be mounted on each of said mounting regions, and said first and second slits intersecting perpendicularly each other;
bonding said semiconductor chips to said substrate member for each of said mounting regions, said semiconductor chip having electrode pads formed in a region matching said first slit; and
dividing said substrate member for each of mounting regions.

10. The method of manufacturing a semiconductor device according to claim 9, further comprising, before dividing said substrate member, the steps of:
forming solder balls on said substrate member;
connecting said solder balls to said electrode pads by way of respective wires; and
burying a resin material in said first and second slits.
